(19) United States
(12) Patent Application Publication
(10) Pub. No.: US 2025/0283406 A1
(43) Pub. Date: Sep. 11, 2025

(54) ADAPTABLE DIGITAL EXECUTION PLAN

(71) Applicant: Schlumberger Technology Corporation, Sugar Land, TX (US)

(72) Inventors: Brian Armstrong, Sugar Land, TX (US); Laurence Fossati, Sugar Land, TX (US); Bo DING, Clamart (FR); Zhandos Ombayev, Sugar Land, TX (US)

(21) Appl. No.: 19/069,645

(22) Filed: Mar. 4, 2025

Related U.S. Application Data
(60) Provisional application No. 63/561,398, filed on Mar. 5, 2024.

(51) Int. Cl. E21B 47/12; E21B 19/00

(52) U.S. Cl. CPC E21B 47/12; E21B 19/008

(57) ABSTRACT

An adaptable digital execution plan system that is configured to perform method steps of automatically monitoring a well during an operation, identifying events of the well during the operation; and updating one or more future DEP based on the identified events. The system may further include the steps of importing caliper data from one or more sources and overlaying the imported caliper data on a user interface.

### CROSS-REFERENCE TO RELATED APPLICATIONS

The present application claims priority to U.S. Provisional Application 63/561,398 dated Mar. 5, 2024, the entirety of which is incorporated by reference.

### FIELD OF THE DISCLOSURE

Aspects of the disclosure relate to downhole tool operations. More specifically, aspects of the disclosure relate to adaptable digital execution plans used to perform tool conveyance with downhole operations.

### BACKGROUND

Conveyance in a well continuously comes with an inherent risk of getting the toolstring stuck during an operation. Sticking of the toolstring which may result in delays and incur additional costs or loss. In order to mitigate such risk, several new methods of conveyance provide a better system, such as an assisted conveyance run.

In essence, when executing an assisted conveyance run, each run has tasks defined using a file called the digital execution plan (DEP). Conventionally, this plan is manually created and reviewed before starting an operation. The time period for creation of this plan can vary but these DEP files could be made days or weeks before an individual run. The current conventional process to create and update the files is done manually; therefore, the fact that these files are usually created before a job means that these files are updated infrequently.

Each assisted conveyance run at a job site happens independently from one another. When performing multiple runs in the same well, the ability to gather information and learn from a previous run is important in enhancing and improving the system. The more information and data that is available to operators and engineers, the greater the likelihood that risks that may be encountered during a run can be mitigated. Currently, engineers use a user interface (UI) overview to identify the depth of a well; however, this UI overview does not provide for any real-time updates of the condition of a well. As a consequence, conventional systems and methods can be improved over the current standards and practices used today.

Conventional wellbore conveyance systems lack an integrated memory system, which significantly impacts their operational efficiency. This absence means that each new operations crew is devoid of reliable historical data to guide their procedures. As a result, each crew must approach the operations with heightened caution, mindful of the potential for the downhole system to become stuck within the wellbore restrictions. This cautious approach is necessary due to the unpredictable nature of wellbore conditions and the lack of prior operational insights.

The economics of wellbore operations necessitate that activities be conducted rapidly and efficiently. Any loss of time in field operations directly affects the overall profitability of the completed wellbore. Delays can lead to increased operational costs, which cumulatively diminish the economic returns of the well. Thus, maximizing operational speed and efficiency is crucial to ensure that the well's economic potential is fully realized.

To achieve maximum efficiency, it is advantageous to employ experienced crews within the same geographic area, as they can leverage previous operational knowledge. However, due to the volatility of oil prices, it is not always feasible to have such experienced crews available for all field operations. The variability in oil costs often leads to fluctuations in crew availability, which can compromise the efficiency and effectiveness of wellbore operations. Ensuring consistency and availability of skilled personnel remains a challenge in maintaining optimal wellbore conveyance systems.

There is a need for a new method and/or system to identify positive and negative events from previous runs and update future runs which would reduce risk and optimize operations as well as leverage existing caliper data and display risks to the engineer in real-time to allow immediate mitigation of any problems.

There is a need to provide an apparatus and methods that are easy to operate both in the field and in planning that will improve upon conventional apparatus and methods.

There is a further need to provide apparatus and methods that do not have the drawbacks discussed above, namely the inability to account for real-time data encountered during operations.

There is a still further need to reduce economic costs associated with operations and apparatus described above with conventional tools.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are therefore not to be considered limiting of its scope, for the disclosure may admit to other equally effective embodiments without specific recitation. Accordingly, the following summary provides just a few aspects of the description and should not be used to limit the described embodiments to a single concept.

In one example embodiment, a method to perform at least one operation in a wellbore according to an adaptable digital execution plan is disclosed. The method may comprise monitoring operations being performed within the wellbore. The method may further comprise identifying events that occur during the operations performed within the wellbore. The method may further comprise updating the adaptable digital execution plan based upon the identified events that occurs during the operations performed within the wellbore.

In another example embodiment, an article of manufacture, containing a list of actions that may be performed upon a computing apparatus is disclosed. In the article of manufacture the list of actions includes, at least in part, a method to perform at least one operation in a wellbore according to an adaptable digital execution plan. The method may comprise monitoring operations being performed within the wellbore. The method may further comprise identifying events that occur during the operations performed within the wellbore. The method may further comprise updating the adaptable digital execution plan based upon the identified events that occur during the operations performed within the wellbore.

In another example embodiment, an adaptable digital execution plan (DEP) system is disclosed. The system may comprise a processor and a memory accessible to the processor. The system may also include processor-executable instructions stored in the memory and executable by the processor to instruct the system to: automatically monitor a well during an operation, identify events of the well during the operation; and update one or more future DEP based on the identified events.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted; however, that the appended drawings illustrate only typical embodiments of this disclosure and are; therefore, not be considered limiting of its scope, for the disclosure may admit to other equally effective embodiments.

FIG. 1 is a diagram illustrating an adaptable digital execution plan system, according to one or more examples of the disclosure.

FIG. 2A is a diagram illustrating an example of a caliper data obtained from a caliper log, according to one or more examples of the disclosure.

FIG. 2B is a diagram illustrating the overlaying of the caliper data from FIG. 2A onto a user interface, according to one or more examples of the disclosure.

FIG. 3 is a method of creating an adaptable digital execution plan in accordance with one example embodiment of the disclosure.

To facilitate understanding, identical reference numerals have been used, where possible, to designate identical elements that are common to the figures (“FIGS.”). It is contemplated that elements disclosed in one embodiment may be beneficially utilized on other embodiments without specific recitation.

### DETAILED DESCRIPTION

In the following, reference is made to embodiments of the disclosure. It should be understood; however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments, and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, components, region, layer or section from another region, layer, or section. Terms such as “first”, “second”, and other numerical terms, when used herein, do not imply a sequence or order unless clearly indicated by the context. Thus, a first element, component, region, layer, or section discussed herein could be termed a second element, component, region, layer, or section without departing from the teachings of the example embodiments.

When an element or layer is referred to as being “on”, “engaged to”, “connected to”, or “coupled to” another element or layer, it may be directly on, engaged, connected, coupled to the other element or layer, or interleaving elements or layers may be present. In contrast, when an element is referred to as being “directly on”, “directly engaged to”, “directly connected to”, or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood; however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

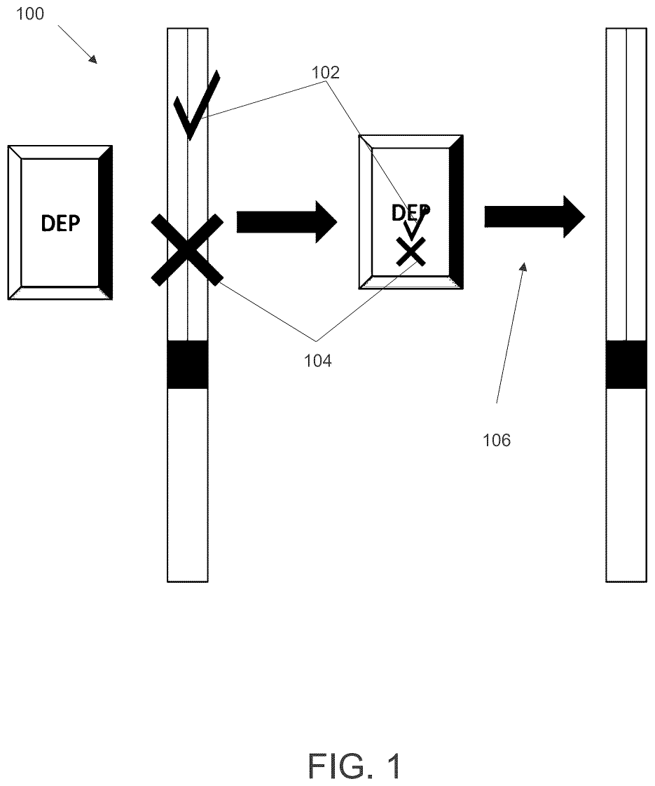

Referring to FIG. 1, aspects of the disclosure provide a new apparatus and method that include an adaptable DEP system 100 that will identify positive and negative events from previous runs. In embodiments, the DEP system 100 will update future runs 106 which would reduce risk and optimize operations.

In one embodiment of the present disclosure, a system that automatically monitors and updates any future DEPs after a current run completes is introduced. In embodiments, this system is active during field operations, such as a downhole wellbore run. Aspects of the disclosure use existing telemetry to silently monitor and record for events. As will be understood, these events could be both positive and negative in nature. As defined herein, positive events 102 would allow the automation system to proceed faster than normal while negative events 104 would slow the system down. Activities that may be increased or decreased may be, for example, winch speeds connected to the downhole tool systems.

A further example of a negative event 104 would be that the system recognizes that the downhole tool hit an unannounced obstruction at a certain depth that required the user to take back manual control. In embodiments, the system and methods would remember this depth and update the DEP so that when the downhole approaches this depth again, activities may automatically slow down to avoid having that user manually take control. Meanwhile, an example of a positive event 102 would be the system recognizing that the downhole tool encountered no obstructions or over a long stretch of depth with minimal tension/weight feedback. These conditions would be a good candidate to have the conveyance speed increased, allowing future runs to be completed faster.

FIG. 1 highlights the adaptable DEP system 100 whereby positive events 102 or negative events 104 are identified and automatically update any future DEP 106, which may help to ensure a more efficient conveyancing with a minimized risk.

In another embodiment of the present disclosure, the adaptable DEP system 100 is also able to leverage existing caliper data and display risks to the engineer in real-time.

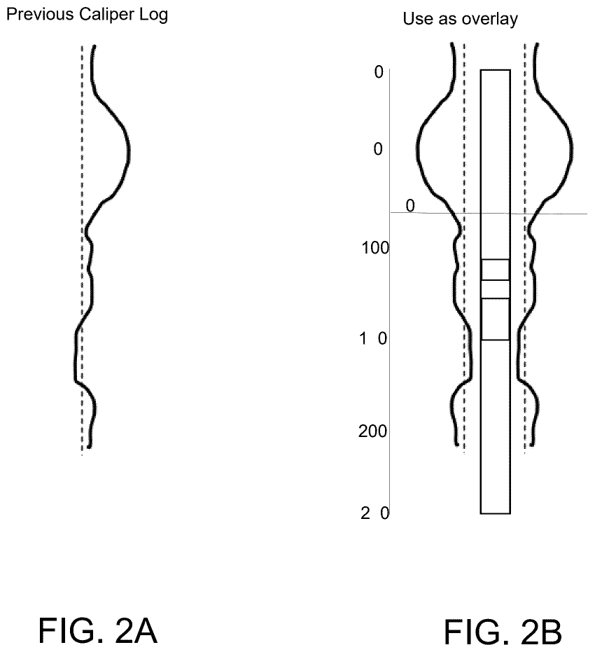

In an embodiment of the present disclosure, the adaptable DEP system 100 is able to import existing caliper data from various sources (DLIS, LAS, CVS) as seen in FIG. 2A. This caliper data would then be overlayed on the UI allowing the engineer to see in the well where cave-ins or sloughing are present as shown in FIG. 2B. By displaying these conditions to the engineer, the operator can make any needed adjustments such as changes to speed or changing the well plan to avoid those areas. As defined herein, DLIS may be files that are placed in a digital log information standard. As further defined herein, LAS may be files that are placed in a log ASCII standard. Such standards may be used in conjunction with field components such as the Schlumberger Log Data Toolbox or other standard log data and graphics systems.

With the adaptable DEP system, operators will be able to monitor the condition of a well, and with the additional information provided by the caliper data, update any future DEPs which will be able to identify any potential risk for future runs, and allow operators to mitigate such risk.

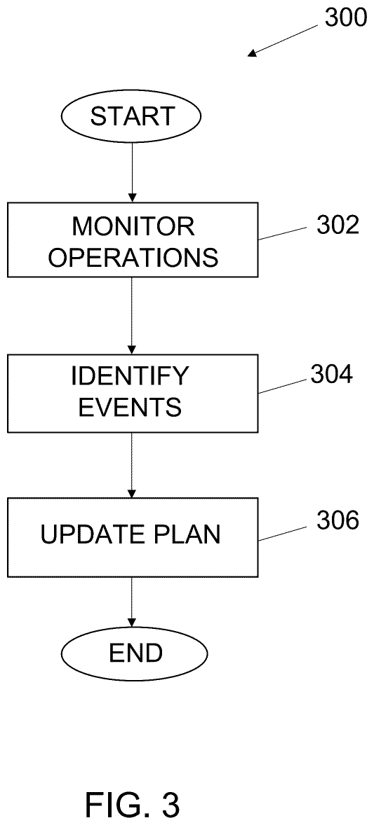

Referring to FIG. 3, a method 300 to create a digital execution plan is illustrated. As will be understood, the digital execution plan may be a list of actions to be completed to accomplish a task. The task may be a discrete task or it may be a series of tasks conducted in parallel or series. The digital execution plan may be “updatable” wherein a preexisting plan may be taken and updated with actions for future execution. Such plans may be stored within a computer system such that in the event of further actions are required in a specific geographic location, such plans may be recalled so that operations crews may conduct activities based upon the most recent field activities. As will be understood, such adaptability may provide a significant improvement upon conventional plans in that operational advantages gained from previous experience may be used each successive time despite different operators being present at the wellbore site or through the passage of time. The method may include, at 302, monitoring operations being performed within the wellbore. The monitoring of the operations may be accomplished in an automatic fashion in that a set of rules may be established. The set of rules may also be based upon threshold values being exceeded, In the even that threshold values being exceeded, an event may be triggered. At 304, the method may include identifying events that occur during the operations performed within the wellbore. As discussed previously, the identifying of an event may be, for example, the exceedance of a threshold value. In embodiments, sensors may be placed throughout the wellbore, rig and downhole equipment to monitor values during field operations. Non-limiting example embodiments of values monitored may include tool depth, winch speed, tool strength length, acceleration, maximum achieved speed as well as other values. At 306, the method may include updating the adaptable digital execution plan based upon the identified events that occur during the operations performed within the wellbore.

In some embodiments, methods described may be stored in a non-volatile memory. In some embodiments, the non-volatile memory may be defined as an article of manufacture. In embodiments, the non-volatile memory is configured such that the methods may contain a list of instructions that may be read by a computing device and the list of instructions performed. The list of instructions may perform calculations, illustrate graphic results on a visual device, such as a monitor, print results or store data for further use, as non-limiting embodiments. The list of instructions may be executable in their own programming or may be executed using other programming. The list of instructions may be stored in various configurations, such as a compact disk, a floppy disk, a solid-state drive, a computer hard drive, a server, a web-oriented storage device, and a cloud-computing device or system. Embodiments of methods described may control other systems, such as machines, to perform specified functions. Operational control may be performed through additional programming and/or operation of other computing or control devices. Embodiments described may be implemented using wireless technologies to allow for computing and execution of the list of instructions from various locations. Computing may occur, for example, in various platforms, including a personal computer, a laptop computer, a computer server, a cloud-based computer, a mainframe computer, a cellular telephone and a cellular connected device.

Embodiments of the methods described may use other programming technologies to help implement the methods described. In some embodiments, machine learning programming may be used to evaluate data and provide results. In some embodiments, training datasets may be used to allow for convergence of needed results and thus using pretrained machine learning programming is considered within the scope of the disclosure. In other instances, artificial intelligence programming systems may be implemented as part of the disclosure or may be incorporated within the methods described. Such artificial intelligence systems may be used in various capacities, including results generation, error detection, problem definition and problem convergence methods. Graphical representation of results obtained by artificial intelligence systems is also considered within the scope of the disclosure.

Aspects of the disclosure provide for a new method and/or system to identify positive and negative events from previous runs and update future runs which would reduce risk and optimize operations as well as leverage existing caliper data and display risks to the engineer in real-time to allow immediate mitigation of any problems.

Aspects of the disclosure provide an apparatus as well as methods that are easier to operate both in the field and in planning that will improve upon conventional apparatus and methods.

Aspects of the disclosure provide apparatus and methods that do not have the drawbacks discussed above, namely the inability to account for real-time data encountered during operations.

Aspects of the disclosure provide reduced economic costs associated with operations and apparatus described above with conventional tools.

Aspects of the claims are described next. This description should not be considered to limit the described embodiments. In one example embodiment, a method to perform at least one operation in a wellbore according to an adaptable digital execution plan is disclosed. The method may comprise monitoring operations being performed within the wellbore. The method may further comprise identifying events that occur during the operations performed within the wellbore. The method may further comprise updating the adaptable digital execution plan based upon the identified events that occurs during the operations performed within the wellbore.

In another example embodiment, the method may be performed wherein monitoring of the operations is performed automatically.

In another example embodiment, the method may be performed wherein the automated monitoring of the well is done using an existing telemetry system.

In another example embodiment, the method may further comprise determining when the identified event is a positive event or a negative event.

In another example embodiment, the method may be performed wherein the positive event indicates that a winch speed for operations being performed within the wellbore may be increased in speed.

In another example embodiment, the method may be performed wherein the negative even indicates that a winch speed for operations for being performed within the wellbore may be decreased in speed.

In another example embodiment, the method may further comprise importing caliper data from at least one source and overlaying imported caliper data on a user interface.

In another example embodiment, the method may further comprise performing the method a second time wherein the adaptable execution plan as updated, is used.

In another example embodiment, the method may be performed wherein during the performing the method the second time, a user interface notifies an operator of changes made to the adaptable digital execution plan prior to performance of the method the second time.

In another example embodiment, the method may be performed wherein the user interface prompts the operator to accept the changes to the adaptable digital execution plan.

In another example embodiment, the method may be performed wherein upon acceptance of the adaptable digital execution plan by the operator, the adaptable digital execution plan is stored in a memory.

In another example embodiment, the method may be performed wherein the memory is a non-volatile memory.

In another example embodiment, an article of manufacture, containing a list of actions that may be performed upon a computing apparatus is disclosed. In the article of manufacture the list of actions includes, at least in part, a method to perform at least one operation in a wellbore according to an adaptable digital execution plan. The method may comprise monitoring operations being performed within the wellbore. The method may further comprise identifying events that occur during the operations performed within the wellbore. The method may further comprise updating the adaptable digital execution plan based upon the identified events that occur during the operations performed within the wellbore.

In another example embodiment, the article of manufacture may be configured wherein the article of manufacture is one form of a solid-state memory arrangement, a universal serial bus device, a computer memory, a computer hard disk and a compact disk.

In another example embodiment, an adaptable digital execution plan (DEP) system is disclosed. The system may comprise a processor and a memory accessible to the processor. The system may also include processor-executable instructions stored in the memory and executable by the processor to instruct the system to automatically monitor a well during an operation, identify events of the well during the operation, and update one or more future DEP based on the identified events.

In another example embodiment, an adaptable digital execution plan system is disclosed wherein the automated monitoring of the well is done using an existing telemetry system.

In another example embodiment, an adaptable digital execution plan system is disclosed wherein the identified events may be a positive event or a negative event.

In another example embodiment, an adaptable digital execution plan system is disclosed wherein the method performed by the system may further comprise the step of importing caliper data from one or more sources and overlaying the imported caliper data on a user interface (UI).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method to perform at least one operation in a wellbore according to an adaptable digital execution plan, comprising:
monitoring operations being performed within the wellbore;
identifying events that occur during the operations performed within the wellbore; and
updating the adaptable digital execution plan based upon the identified events that occur during the operations performed within the wellbore.

2. The method according to claim 1, wherein monitoring of the operations is performed automatically.

3. The method according to claim 2, wherein the automated monitoring of the well is done using an existing telemetry system.

4. The method according to claim 1, further comprising, determining when the identified event is a positive event or a negative event.

5. The method according to claim 4, wherein the positive event indicates that a winch speed for operations being performed within the wellbore may be increased in speed.

6. The method according to claim 4, wherein the negative event indicates that a winch speed for operations for being performed within the wellbore may be decreased in speed.

7. The method according to claim 1, further comprising importing caliper data from at least one source and overlaying imported caliper data on a user interface.

8. The method according to claim 7, wherein the at least one source includes at least one file in a digital log information standard.

9. The method according to claim 7, wherein the at least one source includes at least one file in a log ASCII standard.

10. The method according to claim 1, further comprising:
performing the method a second time wherein the adaptable execution plan as updated, is used.

11. The method according to claim 10, wherein during the performing the method the second time a user interface notifies an operator of changes made to the adaptable digital execution plan prior to performance of the method the second time.

12. The method according to claim 11, wherein the user interface prompts the operator to accept the changes to the adaptable digital execution plan.

13. The method according to claim 12, wherein upon acceptance of the adaptable digital execution plan by the operator, the adaptable digital execution plan is stored in a memory.

14. The method according to claim 13, wherein the memory is a non-volatile memory.

15. An article of manufacture, containing a list of actions that may be performed upon a computing apparatus, the list of actions including, at least in part, a method to perform at least one operation in a wellbore according to an adaptable digital execution plan, comprising:
monitoring operations being performed within the wellbore;
identifying events that occur during the operations performed within the wellbore; and
updating the adaptable digital execution plan based upon the identified events that occurs during the operations performed within the wellbore.

16. The article of manufacture according to claim 15, wherein the article of manufacture is one form of a solid-state memory arrangement, a universal serial bus device, a computer memory, a computer hard disk and a compact disk.

17. An adaptable digital execution plan (DEP) system, the system comprising:
a processor;
a memory accessible to the processor;
processor-executable instructions stored in the memory and executable by the processor to instruct the system to:
automatically monitor a well during an operation;
identify events of the well during the operation; and
update one or more future DEP based on the identified events.

18. The adaptable digital execution plan (DEP) system of claim 17, wherein the automated monitoring of the well is done using an existing telemetry system.

19. The adaptable digital execution plan (DEP) of claim 17, wherein the identified events may be a positive event or a negative event.

20. The adaptable digital execution plan (DEP) of claim 17, further comprising: importing caliper data from one or more sources and overlaying the imported caliper data on a user interface (UI).
